(19) United States
(12) Patent Application Publication
(10) Pub. No.: US 2017/0090768 A1
(43) Pub. Date: Mar. 30, 2017

(54) STORAGE DEVICE THAT PERFORMS ERROR-RATE-BASED DATA BACKUP

(71) Applicant: KABUSHIKI KAISHA TOSHIBA, Tokyo (JP)

(72) Inventors: Itaru KAKIKI, Yokohama Kanagawa (JP); Masatoshi AOKI, Yokohama Kanagawa (JP); Fumitoshi HIDAKA, Yokohama Kanagawa (JP)

(73) Assignee: KABUSHIKI KAISHA TOSHIBA, Tokyo (JP)

(21) Appl. No.: 15/057,556

(22) Filed: Mar. 1, 2016

(30) Foreign Application Priority Data
Sep. 30, 2015 (JP) 2015-194056

(51) Int. Cl. G06F 3/06; G06F 11/07; G11C 29/10

(52) U.S. Cl. CPC G06F 3/065; G11C 29/10; G06F 3/0619; G06F 3/0685; G06F 11/0727; G06F 11/076; G06F 11/0793

(57) ABSTRACT

A storage device includes a first non-volatile storage unit, a second non-volatile storage unit that includes a plurality of semiconductor memory blocks and is capable of executing data access at a speed faster than the first non-volatile storage unit, and a control unit configured to acquire an error value representing an amount of errors included in data read from a block of the second non-volatile storage unit, and carry out a backup of the data either in the first or second non-volatile storage unit, depending on the error value.

### CROSS-REFERENCE TO RELATED APPLICATION

This application is based upon and claims the benefit of priority from Japanese Patent Application No. 2015-194056, filed on Sep. 30, 2015, the entire contents of which are incorporated herein by reference.

### FIELD

Embodiments described herein relate generally to a storage device, in particular, a storage device that performs error-rate-based data backup.

### BACKGROUND

A storage device of one type includes non-volatile storage media of multiple types (for example, two types) that have different access speeds and storage capacities. Such a storage device is known as a hybrid storage device. The hybrid storage device of one type includes in general a non-volatile storage medium, and another non-volatile storage medium, such as a magnetic storage device, that is accessible at a lower access speed and has a larger storage capacity.

### DESCRIPTION OF THE DRAWINGS

FIG. 1 is a block diagram of a storage device according to an embodiment.

FIG. 2 conceptually illustrates a storage area of a NAND memory in the storage device according to the embodiment.

FIG. 3 is a flowchart illustrating an operation of read patrol with respect to the NAND memory according to the embodiment.

### DETAILED DESCRIPTION

One or more embodiments are directed to providing a reliable storage device.

In general, according to an embodiment, a storage device includes a first non-volatile storage unit, a second non-volatile storage unit that includes a plurality of semiconductor memory blocks and is capable of executing data access at a speed faster than the first non-volatile storage unit, and a control unit configured to acquire an error value representing an amount of errors included in data read from a block of the second non-volatile storage unit, and carry out a backup of the data either in the first or second non-volatile storage unit, depending on the error value.

Hereinafter, an embodiment will be described with reference to the accompanying drawings.

In the present disclosure, multiple expressions are used for several elements. Such expressions are merely an example, and these elements may be expressed in other expressions. In addition, elements that are not described with multiple expressions may also be described with different expressions.

In addition, the drawings are merely schematic, and a relationship between a thickness and a planar dimension, a ratio between thickness of each layer, or the like may be different from actual ones. In addition, portions in which relationships between dimensions or ratios between dimensions are different from each other may be included in the drawings.

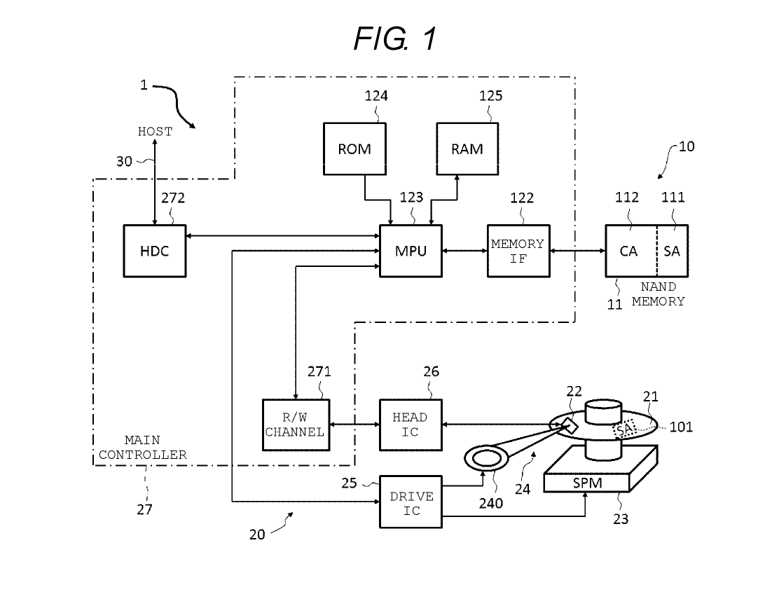

FIG. 1 is a block diagram of a storage device 1 according to the present embodiment. The storage device 1 according to the present embodiment is, for example, a hybrid drive. The hybrid drive includes non-volatile storage media (that is, first non-volatile storage medium and a second non-volatile storage medium) of multiple types, for example, two types, in which access speeds and storage capacities are different from each other. In the present embodiment, the storage device 1 is described as a hybrid drive 1.

In the present embodiment, a magnetic disk medium (hereinafter, referred to as a disk) 21 is used for the first non-volatile storage medium, and NAND flash memory (hereinafter, referred to as NAND memory) 11 is used for the second non-volatile storage medium. The disk 21 includes a system area (SA) 101 for recording management information, as will be described below. Access speed and storage capacity of the disk 21 are respectively slow and large, as compared to those of the NAND flash memory 11.

The hybrid drive 1 illustrated in FIG. 1 includes a semiconductor drive unit 10 such as a solid state drive, and a hard disk drive unit (hereinafter, referred to as an HDD) 20. The semiconductor drive unit 10 includes the NAND memory 11 and a main controller (control unit) 27.

The NAND memory 11 in the hybrid drive 1 is used for various purposes. The NAND memory 11 is used, for example, for performance improvement of the hybrid drive 1, a stable write operation when the hybrid drive 1 vibrates, fast start-up of the hybrid drive 1, or the like. As will be described below, the NAND memory 11 includes a system area (SA) 111 for recording management information.

The main controller 27 controls access to the NAND memory 11 in accordance with an access requirement (for example, a write command or a read command) from a host device (hereinafter, referred to as a host). In the present embodiment, in order to conduct a fast access to the hybrid drive 1 from the host, the NAND memory 11 is used as a cache (cache memory) for storing data which are recently accessed by the host. The host uses the hybrid drive 1 illustrated in FIG. 1 as a storage device therefor.

The main controller 27 is achieved by, for example, a large scale integrated circuit (LSI) in which multiple elements are integrated in a single chip. The main controller 27 includes a memory interface controller (hereinafter, referred to as a memory IF) 122, a microprocessor unit (MPU) 123, a read only memory (ROM) 124, a random access memory (RAM) 125, a read and write (R/W channel) 271, and a hard disk controller (HDC) 272.

The memory IF (first interface controller) 122 is coupled to the NAND memory 11, and accesses the NAND memory 11 under a control of the MPU 123.

The MPU 123 performs processing (for example, write processing or read processing) for accessing the NAND memory 11 based on a command which is transferred from the main controller 27, in accordance with a first control program. In the present embodiment, the first control program is stored in advance in, for example, the ROM 124.

Instead of the ROM 124, a rewritable non-volatile ROM (e.g., a flash ROM) may be used. A portion of the storage area of the RAM 125 is used as, for example, a work area of the MPU 123.

The HDD 20 includes a disk 21, a head 22, a spindle motor (SPM) 23, an actuator 24, a drive integrated circuit (IC) 25, a head IC 26, and the main controller 27.

For example, the disk 21 has a recording surface, in which data are magnetically recorded, on one surface thereof. The disk 21 is rotated fast by the SPM 23. The SPM 23 is driven by a drive current (or drive voltage) which is supplied from the drive IC 25.

FIG. 1 illustrates a configuration of the HDD 20 including a single disk 21. However, the HDD 20 may have multiple disks 21 which are stacked. In addition, in FIG. 1, the disk 21 has a recording surface on one surface thereof. However, the disk 21 may have recording surfaces on both surfaces, and heads may be arranged so as to respectively correspond to both surfaces.

The disk 21 (in more detail, recording surface of the disk 21) has, for example, multiple concentric tracks. The disk 21 may have multiple tracks which are arranged in a spiral shape. The disk 21 has in advance the system area (SA) 101 in a portion of the recording surface.

The system area 101 may be represented by HDD SA 101. Here, management information (HDD management information) on the HDD 20, and information which is the same as management information (NAND management information) on the NAND memory 11 (described below) are retained (recorded) in the system area 101.

The head (head slider) 22 is arranged so as to correspond to the recording surface of the disk 21. The head 22 is attached to the tip of a suspension extending from an arm of the actuator 24.

The actuator 24 includes a voice coil motor (VCM) 240 which becomes a drive source of the actuator 24. The VCM 240 is driven by a drive current (or drive voltage) which is supplied from the drive IC 25. As the actuator 24 is driven by the VCM 240, the head 22 moves in a radial direction of the disk 21 on the disk 21 so as to draw a circular arc.

The drive IC 25 drives the SPM 23 and the VCM 240 under a control of the main controller 27 (in more detail, the MPU 123 in the main controller 27). As the VCM 240 is driven by the drive IC 25, the head 22 is positioned to a target track on the disk 21.

The head IC 26 is also called a head amplifier. For example, the head IC 26 is fixed to a predetermined place of the actuator 24, and is electrically connected to the main controller 27 through a flexible printed circuit board (FPC). However, in FIG. 1, for the sake of convenience of drawing, the head IC 26 is arranged at a position separated from the actuator 24.

The head IC 26 amplifies a signal (that is, a read signal) which is read by a read element of the head 22. In addition, the head IC 26 converts write data which are output from the main controller 27 (in more detail, R/W channel 271 in the main controller 27) into a write current, and outputs the write current to a write element of the head 22.

The R/W channel 271 performs processing of signals in relation to read and write. That is, the R/W channel 271 converts a read signal which is amplified by the head IC 26 into digital data, and decodes the read data from the digital data.

The R/W channel 271 also encodes writ data which are transmitted from the HDC 272, and transmits the encoded write data to the head IC 26.

The HDC 272 is connected to the host through a host interface (storage interface) 30. The host and the hybrid drive illustrated in FIG. 1 are included in an electronic apparatus such as, a personal computer, a video camera, a music player, a mobile terminal, a mobile phone, or a printer device.

The HDC 272 receives a signal which is transmitted from the host, and functions as a host interface controller which transmits a signal to the host. In detail, the HDC 272 receives a command (write command, read command, or the like) which is transmitted from the host, and transfers the received command to the MPU 123.

In addition, the HDC 272 controls data transmission between the host and the HDC 272. The HDC 272 further functions as a disk interface controller which controls data writing to the disk 21 and data reading from the disk 21 through the R/W channel 271, the head IC 26, and the head 22.

The MPU 123 controls an access to the NAND memory 11 in accordance with an access requirement (write requirement or read requirement) from the host, and an access to the disk 21 through the R/W channel 271, the head IC 26, and the head 22. This kind of control is performed by a second control program. In the present embodiment, the second control program is stored in, for example, the ROM 124. A portion of the storage area of the RAM 125 is used as a work area of, for example, the MPU 123.

An initial program loader (IPL) may be stored in the ROM 124, and the second control program may be stored in the disk 21. In this case, it is preferable that, when a power source is connected to the hybrid drive, the MPU 123 operates IPL, whereby the second control program is loaded in the ROM 124 or the RAM 125 from the disk 21.

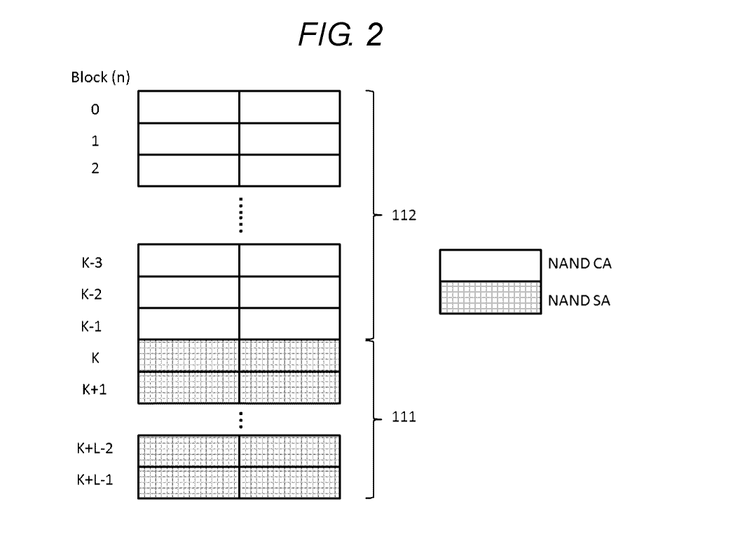

FIG. 2 is a conceptual diagram illustrating a storage area of the NAND memory 11 illustrated in FIG. 1. In FIG. 2, the storage area of the NAND memory 11 includes N (=K+L) programs (that is, physical block). In the NAND memory 11, data are collectively erased by using the data as a unit. That is, block is a unit of data erasure.

The storage area of the NAND memory 11 is divided into, for example, the system area (SA) 111 and a cache area (CA) 112, as illustrated in FIG. 1 and FIG. 2. That is, the NAND memory 11 includes the system area 111 and the cache area 112.

The system area 111 is small enough in general with respect to the cache area 112. The system area 111 of the NAND memory 11 may be referred to as NAND SA 111, and the cache area 112 of the NAND memory 11 may be referred to as NAND CA 112.

In addition, in the present embodiment, the system area 111 includes L blocks, and the cache area 112 includes K blocks. Furthermore, as described above, the system area 111 is smaller in general than the cache area 112, and thus, it is assumed that K>L is satisfied.

The system area 111 is used to store information (NAND management information) which is used for a system (for example, the main controller 27) to manage processing of data reading, data writing, or data erasing with respect to the NAND memory 11. That is, the NAND management information of the NAND memory 11 is retained in the system area 111.

It is preferable that the NAND management information is retained redundantly (multiplexed), and thus backup data of the NAND management information may be retained in the system area 111. For example, the cache area 112 is used to store data with high access frequency from the host. Meanwhile, the cache area 112 may store data with a high access possibility from the host, and may store data which are recently accessed by the data.

The NAND management information includes information of physical configuration of the NAND memory 11, the number of commands (for example, erasing) which are processed with respect to the NAND memory 11, the number of data which are rewritten to the NAND memory 11 as described above, or the like.

Since the minimum unit of writing and the minimum unit of erasing are different from each other in the storage area of the NAND memory 11, only a portion of data cannot be rewritten. For example, in the NAND memory 11, the minimum unit of writing is one page, and the minimum unit of erasing is one block. For example, one block includes 64 pages, but is not limited to this.

An erasing operation of the storage area of the NAND memory 11 is performed by a unit of block, which includes multiple pages as described above. In addition, rewriting (overwriting) operation is not completed by one operation, and data writing is performed after data erasing. That is, since it is necessary to erase the entirety of one block even when one page is rewritten, data of the one block is temporarily retained in another storage area.

The NAND management information retained in the system area 111 is acquired when the hybrid drive starts up (power supply is connected). If the NAND management information cannot be acquired, the entire data in the NAND memory 11 are treated as lost data. One of causes that the NAND management information cannot be acquired is degradation of the storage area (particularly, system area 111) of the NAND memory 11.

A plurality of non-volatile storage media are mounted in the hybrid drive. For example, as a plurality of NAND memories is provided in the hybrid drive, the degradation of the system area of the NAND memory can be suppressed to some extent. However, in this case, as long as an enough number of NAND memories are not mounted, it is not possible to multiplex an enough number of system areas. As a result, degradation of the system area is not sufficiently suppressed.

As a result, the NAND management information cannot be acquired by degradation of the system area in the hybrid drive. If the NAND management information cannot be acquired, reliability of the operation of the hybrid drive is decreased.

For example, an appropriate margin area according to a necessary amount for the NAND management information may be provided in the system area 111, as degradation countermeasure for the storage area of the NAND memory 11. The NAND management information can also be stored in the margin area in the system area 111. As a result, usage concentration of a specified area of the system area 111 can be avoided, writing to the system area 111 can be smoothed, and degradation of the storage area can be reduced.

The system area 111 is used to store, for example, a logical-physical conversion table, a first free area list, a second free area list, and a bad block list. In the following description, the logical-physical conversion table may be referred to simply as a table. In addition, the first free area list, the second free area list, and the bad block list may be referred to simply as a list, respectively.

The logical-physical conversion table is used to store block management information for managing each block in the cache area 112 of the NAND memory 11. In the present embodiment, the block management information is used as cache directory information on addresses of data (each block data) stored in each block (area with a predetermined size) in the cache area 112.

The cache directory information includes information for managing correspondence between a physical address and logical address of each block data. The physical address (here, physical block number) of each block data indicates a position of a block (area) in the NAND memory 11 in which each block data are stored. The logical address (here, a logical block number) of each block data indicates a position in a logical address space of each block data. In general, in the NAND memory, if both the NAND management information and the logical-physical conversion table are not read, preparation of the start-up is not completed.

The first free area list is used to register a free area of a first type in the cache area 112. That is, the first free area list is used as first information for managing the free area of a first type. The free area of a first type indicates a normal free area.

The second free area list is used to register a free area of a second type in the cache area 112. That is, the second free area list is used as second information for managing the free area of a second type. The free area of a second type indicates a free area in which a read error has occurred before. The bad block list is used to register an unusable block (physical block), that is, a bad block (area). That is, the bad block list is used as third information for managing bad blocks.

As described above, in the NAND memory 11, new data (updated data) cannot be overwritten to an area in which data are stored in advance. For this reason, the stored position (memory position) of the table in the system area 111 can be changed whenever the table is updated. In this case, the updated table (new table) can be written to an area different from the area in which a table (old table), which corresponds to data before the update. The stored position of the list in the system area 111 is the same as above.

Information on the stored position and a size of the table, the list, or the like in the system area 111 is stored in a portion of, for example HDD SA 101, NAND SA 111, or the like. In the present embodiment, the information stored in HDD SA 101, NAND SA 111, or the like is read when a power source is connected to the hybrid drive 1, and is loaded in the RAM 125.

It is assumed that each block of the cache area 112 includes multiple pages (physical page). In this case, the logical block also includes multiple pages (logical pages).

A logical page number indicates a logical page (logical page in the logical block) to which pages (physical pages) of a corresponding physical block number and a corresponding physical page number are assigned. That is, the logical page number indicates a position of a logical address space of data which are stored in the corresponding physical page.

In the present embodiment, the main controller 27 performs a read patrol (test read operation) with respect to the NAND memory 11 (in more detail, with respect to the data retained in each block of the NAND memory 11). The read patrol (first processing) according to the present embodiment will be hereinafter described.

In general, the NAND memory 11 has an upper limit with respect to data rewriting. In addition, retaining period of storage content is also limited, and the storage content can be lost by degradation of the NAND memory 11, if a predetermined period of time passes. Here, the predetermined period is, for example, 10 years, but is not limited thereto. In addition, the retaining period of the storage content of the NAND memory 11 is shortened by repeated data writing as described above. In addition, it is also known that the storage content of the retaining period is shortened if the NAND memory 11 is used under high temperature environment.

The main controller 27 determines whether or not data are correctly read, by periodically reading (read patrol is performed) the data retained in each block Block(n) (on condition that 0≦n≦N−1 is satisfied) of the NAND memory 12. Meanwhile, in the present embodiment, the read patrol is periodically performed by, for example, a predetermined periodic cycle.

In the present embodiment, “read patrol” is an operation of reading data retained in each block Block(n), and determining whether or not the read data are correctly read, as described above. In other words, the read patrol is an operation of determining whether or not the data retained in each block Block(n) are damaged. Further, subsequent to the determination, the data (read data) are backed up to a preferable location, so that the data can be correctly read in the future data read operations.

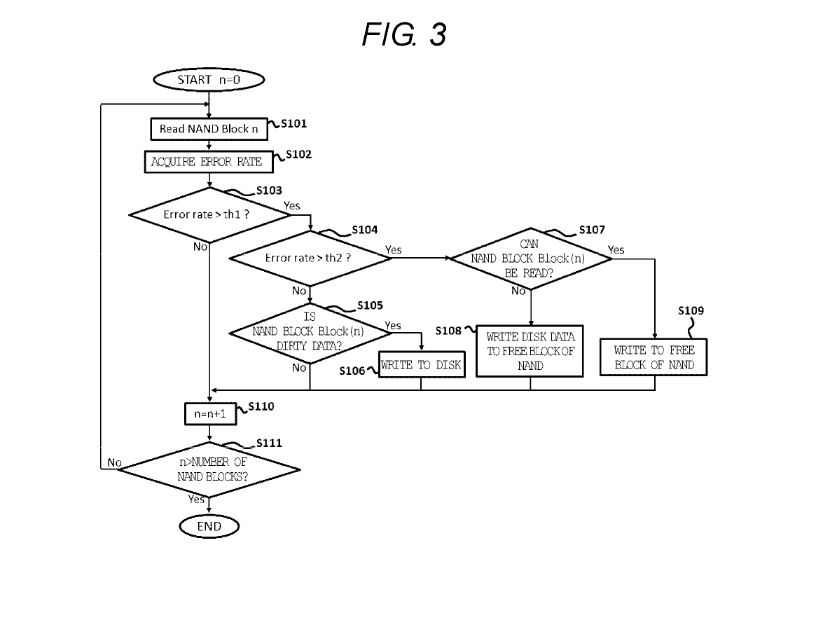

FIG. 3 is a flowchart illustrating an operation of read patrol with respect to the NAND memory 11 according to the present embodiment. Hereinafter, an operation of the storage device 1 will be described with reference to FIG. 3. In the read patrol, the main controller 27 performs data reading from each block of the NAND memory 11, as described above. However, here, it is assumed that the data reading is performed from the block Block(n=0).

The main controller 27 reads first data retained in the block Block(0) of the NAND memory 11 (S101). Meanwhile, an error correction code (ECC) is attached in general to the data retained in the NAND memory 11.

The ECC is a code (error correction code) for correcting an error, in a case in which the error occurs in the data when data are read. Meanwhile, a rate of an error in each data is called an error rate. For example, the error rate indicates a rate of error bits with respect to the number of entire bits of data.

In addition, error correction of ECC has an upper limit, and when the number of error bits is quite great, that is, if the error rate is quite great, the ECC may not correct the error. That is, there is an upper limit of the number (correctable rate) of correctable bits in the ECC. Meanwhile, when the ECC has a high upper limit of the number (correctable rate) of correctable bits, it may be expressed that correction strength of the ECC is high (strong).

Subsequently, an error rate of data which are read in step S101 is acquired (S102). Here, the main controller 27 acquires an error rate of the data which are read from the block Block(0), but may acquire, for example, the number of error bits.

That is, in the present embodiment, the main controller 27 acquires an error amount of the data which are read. Here, the error amount includes an error rate and the number of error bits. Further, in the following description, it is assumed that the main controller 27 acquires an error rate of the data which are read.

The main controller 27 determines whether or not the error rate acquired in step S102 is greater than a first predetermined value th1 (threshold, a first value) (S103).

In step S103, if error rate is greater than th1 (S103:Yes), the main controller 27 determines whether or not the error rate acquired in step S102 is greater than a second predetermined value th2 (threshold, a second value) (S104). However, th1 is smaller than th2.

Meanwhile, if error rate is equal to or smaller than th1 (S103:No), the process proceeds to step S110. An operation after step S110 will be described below.

In step S104, if the error rate is greater than th2 (S104:Yes), the main controller 27 determines whether or not data in the block Block(0) can be correctly read (S107). In other words, the main controller 27 determines whether or not the error of the data in the block Block(0) is (can be) corrected by the ECC.

In step S107, if the data reading is correctly performed (S107:Yes), the main controller 27 writes (backs up) the data which are read from the block Block(0) and then error-corrected to a free block of the NAND memory 11 (S109), and updates the logical-physical conversion table. Here, the free block is a block in which valid data are not retained. In addition, the free block is the free area of a first type described above. Thereafter, the process proceeds to step S110.

Meanwhile, if the data reading is not correctly performed in step S107 (S107:No), the main controller 27 writes (backs up) data corresponding to the data which are not correctly read (i.e., not successfully error-corrected) to a free block (free area of a first type) of the NAND memory 11 (S108), assuming that the corresponding data are stored in the disk 21, and updates the table. Thereafter, the process proceeds to step S110.

In addition, if an answer of the process is No (S107:No), the data retained in the block Block(0) are erased or becomes invalid, and the block Block(0) becomes a free block. Meanwhile, the free block in this case is the free area of a second type.

Subsequently, a process carried out when the error rate is equal to or smaller than th2 (S104:No) will be described. If an answer in step S104 is No (S104:No), the main controller 27 determines whether or not the data in the block Block(0) of the NAND memory 11 are dirty data (S105). The dirty data indicates data which are written to the NAND memory 11 (in more detail, the cache area 112 of the NAND memory 11), and are not written to the disk 21.

In step S105, if the data in the block Block(0) are dirty data (S105:Yes), the main controller 27 writes (backs up) the data read from the block Block(0) and then error-corrected to the disk 21 (S106). Thereafter, the process proceeds to step S110.

Meanwhile, in step S105, if the data in the block Block(0) are not dirty data (S105:No), the process proceeds to step S110.

If answers in steps S103 and S105 are no (S103:No and S105:No), and after steps S106, S108, and S109 are completed, a variable n becomes (n+1) (n=n+1) (S110). That is, n is previously zero (n=0), but n will be one (n=1), and a target block is changed from the block Block(0) to the block Block(1).

Thereafter, the main controller 27 determines whether or not the value of n is greater than the number of blocks (N=K+L) of the NAND memory 11 (S111).

If n>N (S111:Yes), data recognition is completed with respect to the entire blocks of the NAND memory 11, and thus the main controller 27 completes the read patrol.

Meanwhile, if n≦N (S111:No), the process returns to step S101, and data retained in the next block are read. That is, the main controller 27 reads data in the block Block(n=1), and thereafter, the process which is the same as that described above is performed.

In the present embodiment, the main controller 27 performs data reading and confirming (read and verify) with respect to each block of the NAND memory 11. In addition, at the time of the read patrol, a data saving destination is selected by using the first predetermined value th1 having a sufficient margin with respect to the correctable rate of ECC, and the second predetermined value th2 which is greater than the first predetermined value th1, as thresholds.

Specifically, if an error rate of the data read from a certain block Block(n) of the NAND memory 11 is greater than the second predetermined value th2, the main controller 27 writes the data to another free block of the NAND memory 11. If an error rate of the data read from the block Block(n) is greater than the first predetermined value th1 and is less than or equal to the second predetermined value th2, the main controller 27 writes the data to the disk 21.

As described above, the NAND memory 11 has an upper limit for the number of data rewriting operation, and is degraded in accordance with an increase of the number of data rewriting operations. Thus, it is preferable to suppress an increase of the number of data rewriting operations.

In the present embodiment, an error rate of the data which are read is greater than the first predetermined value th1 having a sufficient margin with respect to a correctable rate of ECC. However, if the error rate of the data is less than or equal to the second predetermined value th2 (>th1), the data which are read are written onto the disk 21, if the data are dirty data.

For this reason, an increase of the number of rewriting operations to the NAND memory 11 can be suppressed, and degradation of the NAND memory 11 can be decreased, as compared to a case in which data are written to another free area of the NAND memory 11.

In addition, if an error rate of data which are correctly read is greater than the second predetermined value th2 having smaller margin than the first predetermined value th1 with respect to a correctable rate of ECC, the data which are read are written to another free block of the NAND memory 11.

For this reason, it is possible to prevent performance from degrading, even if there is a high possibility that a read error occurs, as compared to a case in which data are written to the disk 21. That is, since data are saved in the NAND memory 11 when a read error occurs due to data reading from the NAND memory 11, it is not necessary to access the disk 21, and it is possible to maintain fast data reading.

In addition, as another example of degradation countermeasure of the NAND memory 11, a plurality of the NAND memories 11 is provided, each of the NAND memories 11 has the system area 111, and thus it is possible to multiplex data to be recorded. However, in this case, it is necessary to provide a sufficient number of the NAND memories 11, and additional cost can be required.

Meanwhile, in the present embodiment, it is possible to select the data writing destination from another free block of the NAND memory 11, and the disk 21, in accordance with an error rate of data which are read, and thus, degradation of the NAND memory 11 and performance degradation of data access are suppressed. For this reason, it is not necessary to increase the number of the NAND memories 11, or to increase capacity. Accordingly, it is possible to reduce cost and an entire size of the storage device 1.

Meanwhile, the read patrol which is performed in the present embodiment is periodically performed in a predetermined cycle, while power is supplied to, for example, the NAND memory 11. However, the read patrol may be appropriately performed in accordance with a command from the host. In this case, it is possible to control timing for the read patrol in accordance with usage state of the NAND memory 11 or a load of the main controller 27.

Furthermore, it is possible to provide a configuration in which a power source to the NAND memory 11 is disconnected after termination of power supply to the NAND memory 11 is notified to the main controller 27 before the power supply is terminated, and the read patrol is performed in accordance with input from the host.

By providing such a configuration, when the NAND memory 11 is used next time, it is possible to use the NAND memory 11 in a state in which the data retention in the NAND memory 11 is confirmed.

In addition, the main controller 27 may be configured such that the read patrol is initially performed when power supply to the NAND memory 11 is started. Meanwhile, in this case, “initially performing the read patrol” means that the main controller 27 performs the read patrol before processing according to a command is started after receiving the command such as a write requirement or a read requirement from the host. Thus, it is not necessary to perform the read patrol shortly after power is supplied to the NAND memory 11.

Even in this configuration, when the NAND memory 11 is used, it is possible to use the NAND memory 11 in a state in which data retention in the NAND memory 11 is confirmed in advance.

Meanwhile, in the present embodiment, the data writing destination at the time of read patrol is selected when two values of the first predetermined value th1 and the second predetermined value th2 are set as thresholds, but the invention is not limited to this, and the threshold may be set to, for example, three or more.

In addition, in the present embodiment, two values of the first predetermined value th1 and the second predetermined value th2 at the time of read patrol are set as thresholds. However, a series of processing illustrated in FIG. 3 may be performed at the time of reading according to a read requirement from, for example, the host, and may not be performed only at the time of read patrol.

Furthermore, the selection of the data writing destination described in the present embodiment does not need to be performed all the time. For example, exhaustion of the NAND memory 11 may exceed a determined value, and environment temperature around the NAND memory 11 (or storage device 1) may exceed a determined value.

In addition, in the present embodiment, the main controller 27 controls the NAND memory 11 and the disk 21, but the invention is not limited to this, and the NAND memory 11 and the disk 21 may be respectively controlled by controllers different from each other. In this case, the main controller (control unit) 27 according to the present embodiment includes the respective controllers described above.

While certain embodiments have been described, these embodiments have been presented byway of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A storage device, comprising:
a first non-volatile storage unit;
a second non-volatile storage unit that includes a plurality of semiconductor memory blocks and is capable of executing data access at a speed faster than the first non-volatile storage unit; and
a control unit configured to acquire an error value representing an amount of errors included in data read from a block of the second non-volatile storage unit, and carry out a backup of the data either in the first or second non-volatile storage unit, depending on the error value.

2. The storage device according to claim 1, wherein
when the error value is greater than a first value and smaller than a second value that is greater than the first value, the control unit carries out the backup of the data in the first non-volatile storage unit, and
when the error value is greater than the second value, the control unit carries out the backup of the data in the second non-volatile storage unit.

3. The storage device according to claim 2, wherein
when the control unit carries out the backup of the data in the second non-volatile storage unit, the data are written in a block different from the block from which the data are read.

4. The storage device according to claim 2, wherein
when the control unit carries out the backup of the data in the second non-volatile storage unit, the data are erased from the block from which said data are read.

5. The storage device according to claim 2, wherein
the control unit carries out the backup of the data in the first non-volatile storage unit, only when the data are not already stored in the first non-volatile storage unit.

6. The storage device according to claim 2, wherein
when the control unit carries out the backup of the data in the second non-volatile storage unit, corresponding data are read from the first non-volatile storage unit if the data read from the second non-volatile storage unit cannot be error-corrected.

7. The storage device according to claim 1, wherein
the control unit is configured to carry out a test read operation, during which the acquisition of the error value and the backup are carried out with respect to data stored in each block of the second non-volatile storage unit.

8. The storage device according to claim 7, wherein
the control unit periodically carries out the test read operation.

9. The storage device according to claim 7, wherein
the control unit initiates the test read operation in response to a command to start the test read operation, which is received from a host.

10. The storage device according to claim 7, wherein
the control unit initiates the test read operation in response to supply of power to drive the storage device.

11. The storage device according to claim 7, wherein
the control unit initiates the test read operation in response to a notification from a host, the notification indicating that supply of power to drive the storage device is going to be terminated.

12. The storage device according to claim 1, wherein
the first non-volatile storage unit is a magnetic storage unit, and the second non-volatile storage unit is a NAND memory unit.

13. A method for carrying out a backup of data in a storage device including a first non-volatile storage unit and a second non-volatile storage unit that includes a plurality of semiconductor memory blocks and is capable of executing data access at a speed faster than the first non-volatile storage unit, the method comprising:
acquiring an error value representing an amount of errors included in data read from a block of the second non-volatile storage unit; and
carrying out a backup of the data either in the first or second non-volatile storage unit, depending on the error value.

14. The method according to claim 13, wherein
when the error value is greater than a first value and smaller than a second value that is greater than the first value, the backup of the data is carried out in the first non-volatile storage unit, and
when the error value is greater than the second value, the backup of the data is carried out in the second non-volatile storage unit.

15. The method according to claim 14, wherein
when the backup of the data is carried out in the second non-volatile storage unit, the data are written in a block different from the block from which the data are read.

16. The method according to claim 14, wherein
the backup of the data in the first non-volatile storage unit is carried out only when the data are not already stored in the first non-volatile storage unit.

17. The method according to claim 14, wherein
when the backup of the data in the second non-volatile storage unit is carried out, corresponding data are read from the first non-volatile storage unit if the data read from the second non-volatile storage unit cannot be error-corrected.

18. The method according to claim 13, wherein
the acquisition of the error value and the backup are carried out with respect to data stored in each block of the second non-volatile storage unit.

19. The method according to claim 13, wherein
the acquisition of the error value and the backup are carried out, in response to a command transmitted from a host.

20. The method according to claim 13, wherein
the first non-volatile storage unit is a magnetic storage unit, and the second non-volatile storage unit is a NAND memory unit.
